(19) United States
(12) Patent Application Publication
(10) Pub. No.: US 2026/0213495 A1
(43) Pub. Date: Jul. 23, 2026

(54) OPTICAL AMPLIFIER BASED ON GERMANIUM AND OPTICAL INTEGRATED DEVICE INCLUDING THE SAME

(71) Applicant: SAMSUNG ELECTRONICS CO., LTD., Suwon-si (KR)

(72) Inventors: Kyungsang CHO, Suwon-si (KR); Chanwook BAIK, Suwon-si (KR); Youngzoon YOON, Suwon-si (KR)

(73) Assignee: SAMSUNG ELECTRONICS CO., LTD., Suwon-si (KR)

(21) Appl. No.: 19/296,233

(22) Filed: Aug. 11, 2025

(30) Foreign Application Priority Data
Jan. 22, 2025 (KR) 10-2025-0009836

(51) Int. Cl. H01S 5/30

(52) U.S. Cl. CPC H01S 5/3027

(57) ABSTRACT

An optical integrated device includes a first conductive layer, a first semiconductor layer on the first conductive layer and doped with a first-type dopant, a second semiconductor layer on the first semiconductor layer and spaced apart from the first semiconductor layer, the second semiconductor layer being doped with a second-type dopant having a polarity that is opposite to a polarity of the first-type dopant, a second conductive layer on the second semiconductor layer, and a third semiconductor layer between the first semiconductor layer and the second semiconductor layer, the third semiconductor layer including germanium and being configured to amplify light in response to an electrical signal being applied to the first conductive layer and the second conductive layer.

### CROSS-REFERENCE TO RELATED APPLICATION

This application is based on and claims priority under 35 U.S.C. § 119 to Korean Patent Application No. 10-2025-0009836, filed on Jan. 22, 2025, in the Korean Intellectual Property Office, the disclosure of which is incorporated by reference herein in its entirety.

### BACKGROUND

### 1. Field

The disclosure relates to an optical amplifier and an optical integrated device, and more particularly, to an optical amplifier including germanium and an optical integrated device including the optical amplifier.

### 2. Description of Related Art

Recently, wide-area network systems and large data centers for artificial intelligence and big data-based information processing have been widely configured. Because a large-scale information processing system uses many electronic circuits, it is important to improve performance and efficiency and reduce power consumption.

Optical interconnects for configuring efficient optical networks are advantageous for long-distance signal transmission compared to general electrical transmission.

When the power efficiency of optical interconnects increases, the optical interconnects may be used not only for general long-distance signal transmission, but also for transmission of large amounts of information over short distances instead of the electrical transmission methods used for short-distance communication. In particular, as the amount of information to be transmitted increases, the need for fast and efficient optical information transmission increases. Therefore, the development of optical integrated devices is required to increase energy efficiency.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Provided is an optical integrated device including an optical amplifier including germanium.

Additional aspects will be set forth in part in the description which follows and, in part, will be apparent from the description, or may be learned by practice of the presented embodiments of the disclosure.

According to an aspect of the disclosure, an optical integrated device may include a first conductive layer, a first semiconductor layer on the first conductive layer and doped with a first-type dopant, a second semiconductor layer on the first semiconductor layer and spaced apart from the first semiconductor layer, the second semiconductor layer being doped with a second-type dopant having a polarity that is opposite to a polarity of the first-type dopant, a second conductive layer on the second semiconductor layer, and a third semiconductor layer between the first semiconductor layer and the second semiconductor layer, the third semiconductor layer including germanium and being configured to amplify light in response to an electrical signal being applied to the first conductive layer and the second conductive layer.

The third semiconductor layer may include an intrinsic semiconductor.

The third semiconductor layer may include at least one of Ge and GeₓSi₁₋ₓ, with (0<x<1).

Each of the first semiconductor layer and the second semiconductor layer may include silicon (Si).

The first semiconductor layer may include silicon (Si), and the second semiconductor layer may include germanium (Ge).

The first semiconductor layer may include a first sub-semiconductor layer on the first conductive layer and including silicon (Si) and a second sub-semiconductor layer on the first sub-semiconductor layer and including germanium (Ge).

A width of the third semiconductor layer may be less than or equal to a width of the first semiconductor layer and a width of the second semiconductor layer.

The second semiconductor layer may include a first region on the third semiconductor layer and having a width that is greater than a width of the third semiconductor layer, and a second region on the first region and having a width that is less than the width of the first region.

The optical integrated device may include a dielectric layer on the first region and contacting a side surface of the second region.

The dielectric layer may include at least one of a silicon oxide and a silicon nitride.

The optical integrated device may include a fourth semiconductor layer between the first semiconductor layer and the second semiconductor layer, the fourth semiconductor layer contacting a side surface of the third semiconductor layer.

The fourth semiconductor layer may include silicon (Si).

The optical integrated device may include fifth semiconductor layer including an amorphous material and between the first semiconductor layer and the third semiconductor layer.

The fifth semiconductor layer may include at least one of Ge and GeₓSi₁₋ₓ, with (0<x<1).

A thickness of the fifth semiconductor layer may be less than a thickness of the third semiconductor layer.

The optical integrated device may include a waveguide configured to transmit light passing therethrough to the third semiconductor layer.

The optical integrated device may include an anti-reflection layer between the waveguide and the third semiconductor layer and configured to prevent reflection of incident light.

According to an aspect of the disclosure, an optical amplifier may include a first semiconductor layer doped with a first-type dopant at a first concentration, a second semiconductor layer on the first semiconductor layer and spaced apart from the first semiconductor layer, the second semiconductor layer being doped with a second-type dopant having a polarity that is opposite to a polarity of the first-type dopant, a conductive layer on the second semiconductor layer, a third semiconductor layer on the first semiconductor layer and doped with the first-type dopant at a second concentration that is greater than the first concentration, and a fourth semiconductor layer between the first semiconductor layer and the second semiconductor layer, the fourth semiconductor layer including germanium and being configured to amplify light in response to an electrical signal being applied to the conductive layer and the second semiconductor layer.

The third semiconductor layer may include at least one of Ge and GeₓSi₁₋ₓ, with (0<x<1).

Each of the first semiconductor layer and the second semiconductor layer may include silicon (Si).

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a diagram illustrating an optical amplifier including germanium, according to one or more embodiments;

FIG. 2 is a diagram illustrating an optical amplifier including germanium, according to one or more embodiments;

FIG. 3 is a diagram illustrating an optical amplifier including an amorphous semiconductor layer, according to one or more embodiments;

FIG. 4 is a diagram illustrating an optical amplifier including an amorphous semiconductor layer, according to one or more embodiments;

FIG. 5 is a diagram illustrating an optical amplifier including a high-concentration semiconductor layer, according to one or more embodiments;

FIG. 6 is a diagram illustrating an optical integrated device including a waveguide and an optical amplifier, according to one or more embodiments;

FIG. 7 is a diagram illustrating an optical integrated device including an anti-reflection layer according to one or more embodiments;

FIG. 8 is a diagram illustrating a configuration of a phase array element, which is an example of an optical integrated device, according to one or more embodiments; and

FIG. 9 is a block diagram illustrating an optical communication system including an optical integrated device according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, embodiments are described in detail with reference to the attached drawings. The embodiments to be described are merely examples, and various modifications may be derived therefrom. In the following drawings, the same reference numerals refer to the same components, and a size of each component in the drawings may be exaggerated for the sake of clear and convenient description.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms, such as “first”, “second”, and so on may be used to describe various components, but are used only for the purpose of distinguishing one component from another component. The terms do not limit materials or structures of the components.

Singular expressions include plural expressions unless the context clearly indicates otherwise. In addition, when a portion “includes” a certain component, this means that other components may be further included rather than excluding other components unless specifically stated to the contrary.

Also, the terms “portion/unit”, “module”, or so on described in the specification mean a unit that processes at least one function or operation, which may be implemented with hardware or software, or a combination of hardware and software.

The specific implementations described in the embodiments are examples and do not limit the technical scope in any way. In order to simplify the specification, descriptions of conventional electronic components, control systems, software, and other functional aspects of the above systems may be omitted. Also, connections or lack of connections between the components illustrated in the drawings are merely examples of functional connections and/or physical or circuit connections, and may be represented in actual devices as alternative or additional various functional connections, physical connections, or circuit connections.

The use of the term “above” and similar referential terms may refer to both a singular expression and a plural expression.

Operations of methods may be performed in any suitable order unless there is an explicit statement that the operations have to be performed in the order described. Also, the use of all example terms (for example, and so on) is intended merely to describe the technical idea and does not limit the scope of the claims by such terms unless otherwise defined by the claims.

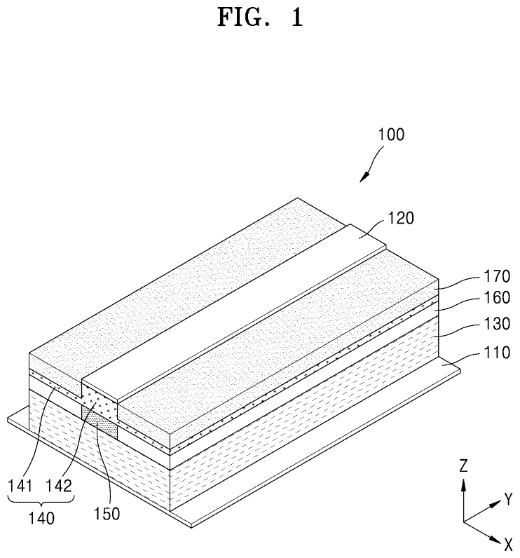

FIG. 1 is a diagram illustrating an optical amplifier 100 including germanium, according to one or more embodiments. Referring to FIG. 1, the optical amplifier 100 may include a first conductive layer 110 and a second conductive layer 120 spaced apart from each other in a thickness direction (a Z-axis direction) of the optical amplifier 100, a first semiconductor layer 130 and a second semiconductor layer 140 provided between the first conductive layer 110 and the second conductive layer 120 and spaced apart from each other in the thickness direction (the Z-axis direction) of the optical amplifier 100, and a third semiconductor layer 150 including germanium which is between the first semiconductor layer 130 and the second semiconductor layer 140 and amplifies light in response to an electrical signal being applied to the first conductive layer 110 and the second conductive layer 120. The optical amplifier 100 may be an optical element of an optical integrated device. The optical integrated device may further include various optical elements, such as a waveguide, a light detector, a light source, and an optical modulator in addition to the optical amplifier 100.

The optical amplifier 100 may include the first conductive layer 110 and the second conductive layer 120 spaced apart from each other in the thickness direction (the Z-axis direction) of the optical amplifier 100. A width of the first conductive layer 110 may be greater than or equal to a width of the second conductive layer 120. For example, the width of the first conductive layer 110 may be greater than the width of the second conductive layer 120. That is, the width of the first conductive layer 110 in the width direction (the X-axis direction) may be greater than or equal to the width of the second conductive layer 120 in the width direction (the X-axis direction).

At least one of the first conductive layer 110 and the second conductive layer 120 may include a metal, an alloy, a metal nitride, a silicide, or so on. The metal may include, for example, Au, Al, Ag, Cu, Pt, Ni, W, Ti, Mo, Ru, Ge, Ta, Hf, Nb, Zr, or V. The alloy may include, for example, AlNd. The metal nitride may include, for example, TiN, AlN, TaN, Ta₂N, Ta₃N₅, W₂N, WN, or WN₂. The silicide may include, for example, TiSi, TiSi₂, Ti₅Si₃, VSi₂, FeSi₂, CoSi₂, PtSi, Pt₂Si, NiSi, NiSi₂, Ni₂Si, Cu₃Si, YSi, ZrSi, NbSi₂, MoSi₂, PdSi, Pd₂Si, ErSi, YbSi, YbSi₂, ZrSi₂, HfSi, HfSi₂, TaSi, TaSi₂, NbSi, NbSi₂, ZrSi, ZrSi₂, VSi, VSi₂, WSi, WSi₂, GeSi, OsSi, IrSi, IrSi₃, AlSi, CuSi, RuSi, or Ru₂Si₃.

The first semiconductor layer 130 may be on the first conductive layer 110. The first semiconductor layer 130 may include silicon. The first semiconductor layer 130 may be doped with a p-type dopant or an n-type dopant. The p-type dopant may include B, Al, Ga, In, Te, or so on, and the n-type dopant may include P, As, Sb, or so on.

The second semiconductor layer 140 may be spaced apart from the first semiconductor layer 130 in the thickness direction (the Z-axis direction) of the first semiconductor layer 130. The second semiconductor layer 140 may include silicon. The second semiconductor layer 140 may be doped with a dopant having a different conductivity type from a dopant doped in the first semiconductor layer 130. For example, when the first semiconductor layer 130 is doped with an n-type dopant, the second semiconductor layer 140 may be doped with a p-type dopant. Alternatively, when the first semiconductor layer 130 is doped with a p-type dopant, the second semiconductor layer 140 may be doped with an n-type dopant. The p-type dopant may include B, Al, Ga, In, Te, or so on, and the n-type dopant may include P, As, Sb, or so on.

The third semiconductor layer 150 may be between the first semiconductor layer 130 and the second semiconductor layer 140. The third semiconductor layer 150 may include at least one of Ge and GeₓSi₁₋ₓ (0<x<1). The third semiconductor layer 150 may be formed of an intrinsic semiconductor that is not doped with a dopant.

A width of the third semiconductor layer 150 in the width direction (the X-axis direction) may be less than a width of the first semiconductor layer 130 in the width direction (the X-axis direction) and a width of the second semiconductor layer 140 in the width direction (the X-axis direction). The light transmitted through a waveguide may have a high light density while incident on the third semiconductor layer 150. The light incident on the third semiconductor layer 150 may have a wavelength of about 1,100 nm to about 1,800 nm.

The light may pass through the third semiconductor layer 150 in the longitudinal direction of the third semiconductor layer 150 (for example, in a Y-axis direction). When passing through the third semiconductor layer 150, the light may be amplified by an electrical signal applied to the first conductive layer 110 and the second conductive layer 120. For example, when a voltage is applied to the first conductive layer 110 and the second conductive layer 120, the first semiconductor layer 130 and the second semiconductor layer 140 may each provide carriers (holes or electrons) to the third semiconductor layer 150. The carriers may amplify the light by increasing power of the light passing through the third semiconductor layer 150 through stimulated emission. A wavelength of the amplified light may be determined by a band gap of a material included in the third semiconductor layer 150. The degree of amplification of the light may be determined by intensity of the electrical signal applied to the first conductive layer 110 and the second conductive layer 120.

A fourth semiconductor layer 160 may be on the first semiconductor layer 130 to surround a side surface of the third semiconductor layer 150. That is, the fourth semiconductor layer 160 may contact one or more side surfaces of the third semiconductor layer 150 along the entire length of the respective side surface of the third semiconductor layer 150. The fourth semiconductor layer 160 may completely cover the side surfaces of the third semiconductor layer 150. The fourth semiconductor layer 160 may include the same material as the first semiconductor layer 130. For example, the fourth semiconductor layer 160 may include silicon. The fourth semiconductor layer 160 may be formed of an intrinsic semiconductor.

A width of at least one of the first conductive layer 110 and the second conductive layer 120 may be similar to a width of the third semiconductor layer 150 in the width direction (the X-axis direction). For example, the width of the second conductive layer 120 may be equal to the width of the third semiconductor layer 150, and the width of the first conductive layer 110 may be greater than the width of the third semiconductor layer 150.

When the width of the first conductive layer 110 is greater than the width of the second conductive layer 120, the second semiconductor layer 140 may include a first region 141 on the third semiconductor layer 150 and having a width greater than the width of the third semiconductor layer 150, and a second region 142 on the first region 141 (e.g., protruding from the first region 141 in the +Z direction) and having a width less than the width of the first region 141 in the width direction (the X-axis direction).

The optical amplifier 100 may further include a dielectric layer 170 arranged on the first region 141 and surrounding a side surface of the second region 142. That is, the dielectric layer 170 may contact one or more side surfaces of the second region 142 along the entire length of the respective side surface of the second region 142. The dielectric layer 170 may completely cover the side surfaces of the second region 142 while being provided on the top surfaces of the first region 141. A current may flow through the first semiconductor layer 130, the third semiconductor layer 150, and the second semiconductor layer 140 by an electrical signal applied to the first conductive layer 110 and the second conductive layer 120. The dielectric layer 170 may prevent a current from concentrating in the third semiconductor layer 150 and from flowing to other layers.

The dielectric layer 170 may include silicon oxide (SiO₂) but is not limited thereto. The dielectric layer 170 may include at least one of an insulating silicon compound and an insulating metal compound in addition to the silicon oxide. The insulating silicon compound may include, for example, silicon nitride (SiₓN_{y}), silicon oxynitride (SiON), and so on.

An information transmission system using light, such as an optical interconnect, an optical memory, or optical communication, may decrease in light intensity as a signal transmission distance increases and the number of signal processing processes increases. The light detector, which is the final signal detection unit, may receive light with minimum intensity that may be detected.

In order to increase the light intensity, power of a light source may be required to be increased, or the light may be required to be amplified during a light transmission process. Increasing the power of the light source increases the driving power of the light source, increases costs, and deteriorates the light source. Therefore, most optical integrated devices may increase the light intensity by using the optical amplifier 100.

In addition, an optical integrated device using light in the range of 1,310 nm to 1,550 nm may be manufactured based on a silicon material and a process. In addition, an optical amplifier may be made of an III-V compound, such as GaAs. However, III-V materials are hardly grown on a silicon wafer. Therefore, the optical amplifier may be grown through a separate III-V process, and a process of transferring the grown optical amplifier may be required. In this case, costs and time for expensive III-V substrates, III-V processes, transfer processes, and so on are required, and there is difficulty in mass production.

In addition, germanium may be grown and patterned on a silicon layer in a silicon process line. Therefore, in one or more embodiments, by manufacturing an optical amplifier by using germanium that may be mass-produced in a silicon-based process, costs and time may be reduced.

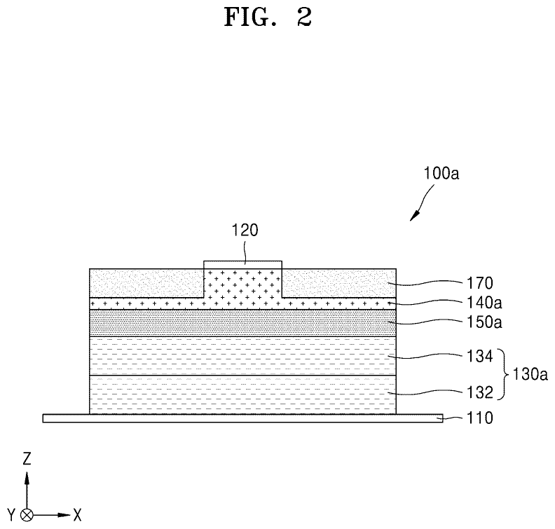

FIG. 2 is a diagram illustrating an optical amplifier 100a including germanium, according to one or more embodiments. A first semiconductor layer 130a of the optical amplifier 100a illustrated in FIG. 2 may be doped with a first-type dopant, and a second semiconductor layer 140a may be doped with a second-type dopant having a polarity opposite to a polarity of the first-type dopant. For example, the first semiconductor layer 130a may be doped with an n-type dopant, and the second semiconductor layer 140a may be doped with a p-type dopant.

Comparing FIG. 1 with FIG. 2, the first semiconductor layer 130a may include a first sub-semiconductor layer 132 formed of silicon and a second sub-semiconductor layer 134, which is arranged on the first sub-semiconductor layer 132 and formed of germanium. In addition, the second semiconductor layer 140a may be formed of germanium.

A third semiconductor layer 150a arranged between the first semiconductor layer 130a and the second semiconductor layer 140a may be formed of an intrinsic semiconductor that is not doped with a dopant. The third semiconductor layer 150a may be formed of at least one of Ge and GeₓSi₁₋ₓ (0<x<1). Because the optical amplifier 100a is formed of a silicon layer doped with a first-type dopant, a germanium layer doped with the first-type dopant, and a semiconductor layer based on intrinsic germanium which are sequentially formed, defects due to lattice mismatch may be reduced. Also, because defects are reduced, a width of the third semiconductor layer 150 through which light passes may be increased. For example, the width of the third semiconductor layer 150 may be equal to a width of the second

### Semiconductor Layer 140.

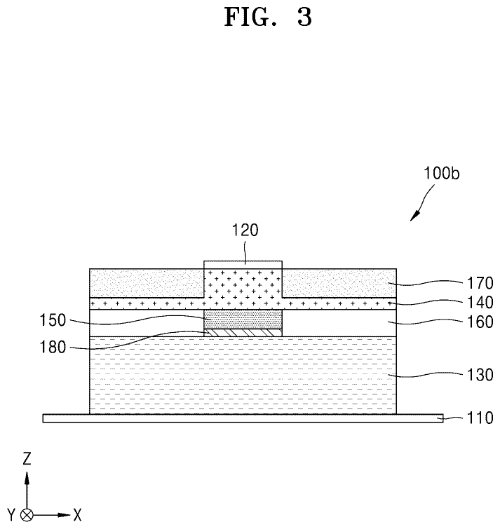

FIG. 3 is a diagram illustrating an optical amplifier 100b including an amorphous semiconductor layer, according one or more embodiments. Comparing FIG. 1 with FIG. 3, the optical amplifier 100b of FIG. 3 may further include a fifth semiconductor layer 180, which is an amorphous semiconductor layer, between the first semiconductor layer 130 and the third semiconductor layer 150. The fifth semiconductor layer 180 may be formed of an amorphous material of Ge or GeₓSi₁₋ₓ (0<x<1). Because the fifth semiconductor layer 180 is an amorphous semiconductor layer, the fifth semiconductor layer 180 may reduce a lattice mismatch between the first semiconductor layer 130 and the third semiconductor layer 150.

A width of the fifth semiconductor layer 180 may be less than or equal to a width of the first semiconductor layer 130 and greater than or equal to a width of the third semiconductor layer 150 in the width direction (the X-axis direction). For example, the width of the fifth semiconductor layer 180 may be less than the width of the first semiconductor layer 130, and equal to the width of the third semiconductor layer 150 in the width direction (the X-axis direction). A thickness of the fifth semiconductor layer 180 may be less than a thickness of the third semiconductor layer 150 in the Z-axis direction. For example, the thickness of the fifth semiconductor layer 180 may be half or less than the thickness of the third semiconductor layer 150.

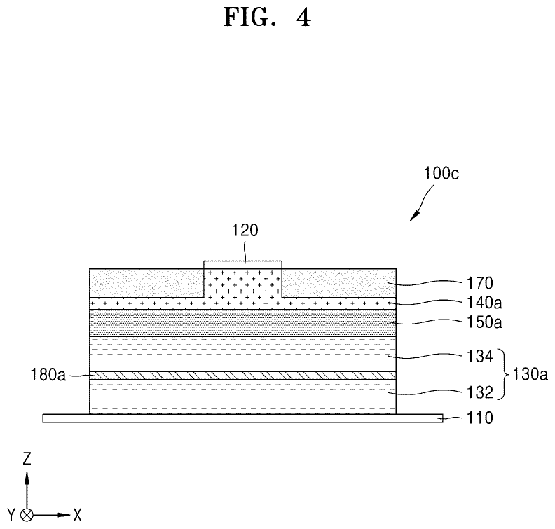

FIG. 4 is a diagram illustrating an optical amplifier 100c including an amorphous semiconductor layer, according to one or more embodiments. Comparing FIG. 2 with FIG. 4, the optical amplifier 100c of FIG. 4 may further include a fourth semiconductor layer 180a, which is an amorphous semiconductor layer, between the first sub-semiconductor layer 132 and the second sub-semiconductor layer 134. The fourth semiconductor layer 180a may be formed of at least one of Ge and GeₓSi₁₋ₓ (0<x<1), which are amorphous materials. Because the fourth semiconductor layer 180a is an amorphous semiconductor layer, the fourth semiconductor layer 180a may reduce a lattice mismatch between the first sub-semiconductor layer 132 and the second sub-semiconductor layer 134.

A width of the fourth semiconductor layer 180a may be equal to a width of the first sub-semiconductor layer 132 and a width of the second sub-semiconductor layer 134 in the width direction (the X-axis direction). A thickness of the fourth semiconductor layer 180a may be less than a thickness of the first sub-semiconductor layer 132 and a thickness of the second sub-semiconductor layer 134 in the Z-axis direction. For example, the thickness of the fourth semiconductor layer 180a may be half or less than the thickness of the first sub-semiconductor layer 132 and the thickness of the second sub-semiconductor layer 134.

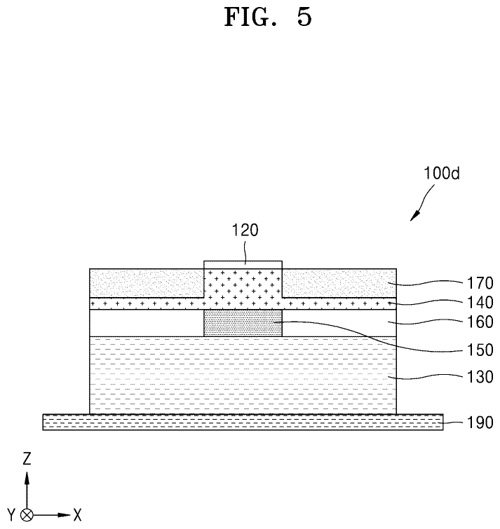

FIG. 5 is a diagram illustrating an optical amplifier 100d including a high-concentration semiconductor layer, according one or more embodiments. Comparing FIG. 1 with FIG. 5, the optical amplifier 100d of FIG. 5 may include a sixth semiconductor layer 190 with a high concentration instead of the first conductive layer 110. A material of the sixth semiconductor layer 190 may be the same as a material of the first semiconductor layer 130. For example, the sixth semiconductor layer 190 may be formed of silicon and may be doped with a first-type dopant. A doping concentration of the sixth semiconductor layer 190 may be greater than a doping concentration of the first semiconductor layer 130.

The light may pass through the third semiconductor layer 150 in the longitudinal direction (for example, the Y-axis direction) of the third semiconductor layer 150. When passing through the third semiconductor layer 150, the light may be amplified by an electrical signal applied to the sixth semiconductor layer 190 and the second conductive layer 120. For example, when a voltage is applied to the sixth semiconductor layer 190 and the second conductive layer 120, each of the first semiconductor layer 130 and the second semiconductor layer 140 may provide carriers (holes or electrons) to the third semiconductor layer 150. The carriers may amplify the light by increasing the power of light passing through the third semiconductor layer 150 through stimulated emission. A wavelength of the amplified light may be determined by a band gap of a material included in the third semiconductor layer 150. The degree of amplification of the light may be determined by intensity of an electrical signal applied to the first conductive layer 110 and the second conductive layer 120.

The first conductive layer 110 illustrated in FIGS. 2 to 4 may also be replaced with a sixth semiconductor layer 190 with a high dopant concentration. Alternatively, the sixth semiconductor layer 190 may be further arranged between the first conductive layer 110 and the first semiconductor layer 130 illustrated in FIGS. 1 to 4.

The optical amplifiers 100, 100a, 100b, 100c, and 100d described above may be components of an optical integrated device together with a waveguide.

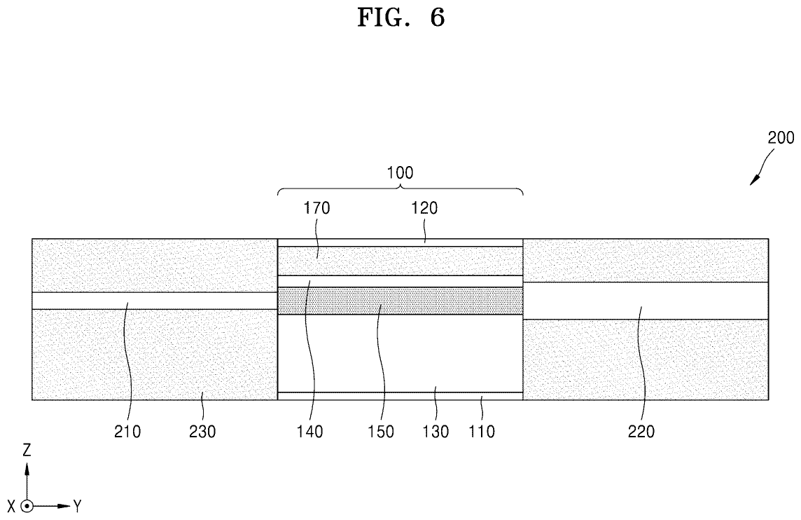

FIG. 6 is a diagram illustrating an optical integrated device including a waveguide and an optical, amplifier according one or more embodiments.

Referring to FIG. 6, an optical integrated device 200 may include a first waveguide 210, an optical amplifier 100, and a second waveguide 220. The first waveguide 210 may transmit light to the optical amplifier 100, and the second waveguide 220 may receive the amplified light from the optical amplifier 100. FIG. 6 illustrates the optical amplifier 100 of FIG. 1. However, the disclosure is not limited thereto. The optical amplifiers 100a, 100b, 100c, and 100d illustrated in FIGS. 2 to 5 may also be applied to the optical integrated device 200.

The first waveguide 210 and the second waveguide 220 may be arranged on a dielectric layer 230. The first waveguide 210 and the second waveguide 220 may each be formed of a material having a refractive index greater than a refractive index of the dielectric layer 230. The first waveguide 210 and the second waveguide 220 may each be formed of a semiconductor material. The dielectric layer 230 may include at least one of a silicon oxide and a silicon nitride. For example, the first waveguide 210 and the second waveguide 220 may each be formed by partially patterning a silicon layer on a silicon on insulator (SOI) substrate.

A cross-sectional height in the Z-axis direction of the first waveguide 210 contacting the optical amplifier 100 may be less than or equal to a cross-sectional height in the Z-axis direction of the third semiconductor layer 150 of the optical amplifier 100. For example, the entire cross-sectional height in the Z-axis direction of the first waveguide 210 contacting the optical amplifier 100 in an optical axis direction (a Y-axis direction) may be within a cross-sectional height in the Z-axis direction of the third semiconductor layer 150 (i.e., the top and bottom of the first waveguide 210 contacting the side surface of the third semiconductor layer 150 may be within the top and bottom of the third semiconductor layer 150). Accordingly, most of the light of the first waveguide 210 may pass through the third semiconductor layer 150. However, the disclosure is not limited thereto. More than 80% of the cross-sectional height in the Z-axis direction of the first waveguide 210 contacting the optical amplifier in the optical axis direction (the Y-axis direction) may also be within the cross-sectional height in the Z-axis direction of the third semiconductor layer 150.

The cross-sectional height in the Z-axis direction of the second waveguide 220 contacting the optical amplifier 100 may be greater than or equal to the cross-sectional height in the Z-axis direction of the third semiconductor layer 150 of the optical amplifier 100. For example, the entire cross-sectional height in the Z-axis direction of the second waveguide 220 contacting the optical amplifier 100 in the optical axis direction (the Y-axis direction) may be greater than a cross-sectional height in the Z-axis direction of the third semiconductor layer 150, such that the top and bottom of the third semiconductor layer 150 in the Z-axis direction may be within the top and bottom of the second waveguide 220 in the Z-axis direction. Accordingly, most of the light of the optical amplifier 100 may pass through the second waveguide 220.

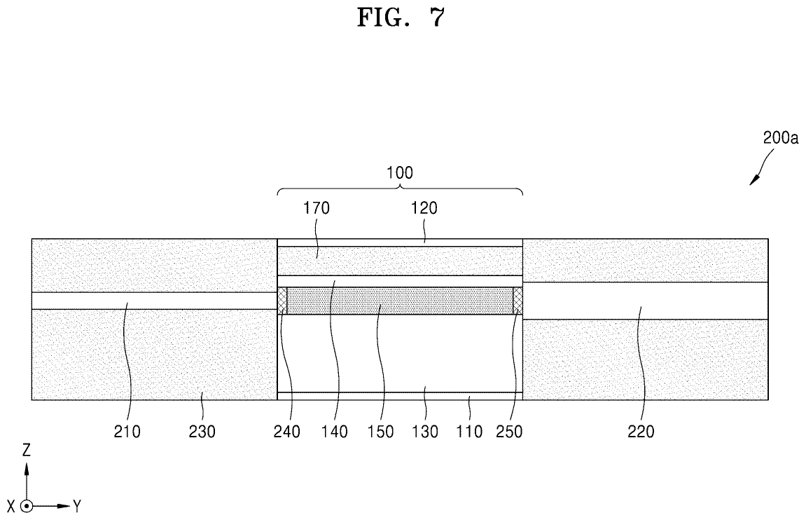

FIG. 7 is a diagram illustrating an optical integrated device including an anti-reflection layer according one or more embodiments. Comparing FIG. 6 with FIG. 7, an optical integrated device 200a may further include at least one of a first anti-reflection layer 240 arranged between the first waveguide 210 and the optical amplifier 100 and a second anti-reflection layer 250 arranged between the optical amplifier 100 and the first waveguide 210.

The first anti-reflection layer 240 may prevent the light incident from the first waveguide 210 to the optical amplifier 100 from being reflected to the first waveguide 210, and the second anti-reflection layer 250 may prevent the light incident from the optical amplifier 100 to the second waveguide 220 from being reflected to another optical amplifier. For example, a wavelength of the light reflected at an interface between the first anti-reflection layer 240 and the optical amplifier 100 and an interface between the optical amplifier 100 and the first anti-reflection layer 240 may be reduced and interfered with each other, and accordingly, reflectivity may be reduced, and transmittance may be improved. At least one of the first anti-reflection layer 240 and the second anti-reflection layer 250 may include at least one of MgF₂, SiO₂, Al₂O₃, HfO₂, and Ta₂O₅ but is not limited thereto. Therefore, light incidence efficiency and/or light emission efficiency of the optical amplifier 100 may be improved.

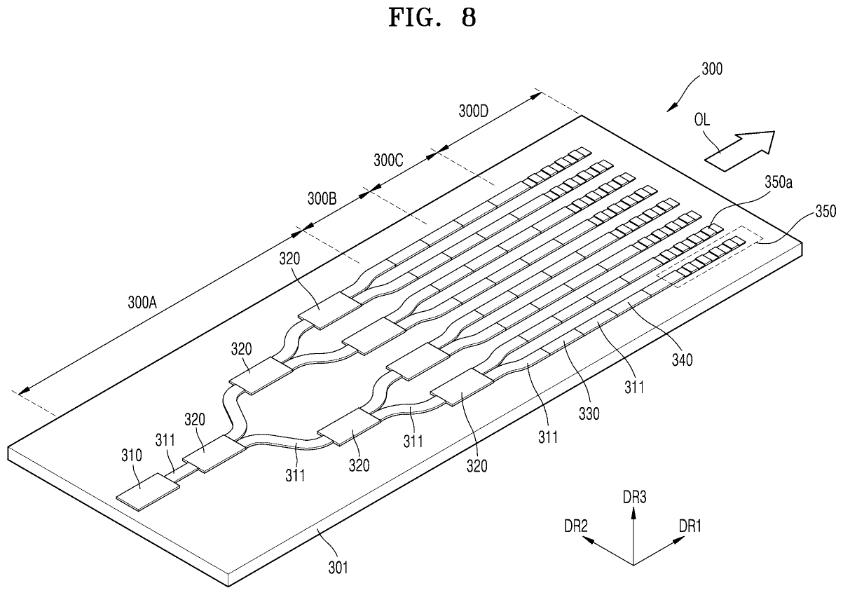

FIG. 8 is a diagram illustrating a configuration of a phase array element which is an example of an optical integrated device according one or more embodiments. Referring to FIG. 8, an optical phase array element 300 may include a light source 310, a branch region 300A, a phase control region 300B, an amplification region 300C, and an emission region 300D arranged on a substrate 301. The light source 310, the branch region 300A, the phase control region 300B, the amplification region 300C, and the emission region 300D may be arranged in a first direction DR1. Also, the optical phase array element 300 may include a plurality of waveguides 311 that sequentially transmit the light generated by the light source 310 to the branch region 300A, the phase control region 300B, the amplification region 300C, and the emission region 300D. The light generated by the light source 310 may pass through the plurality of waveguides 311 in the first direction DR1.

The branch region 300A may include a plurality of optical splitters 320. The plurality of optical splitters 320 may each split the light passing through the waveguide 311 into multiple beams of light. To this end, one waveguide 311 may be connected to an input terminal of each of the plurality of optical splitters 320 and multiple waveguides 311 may be connected to an output terminal of each of the plurality of optical splitters 320. For example, the plurality of optical splitters 320, each splitting the light into two beams of light, are illustrated in FIG. 8. The light generated by the light source 310 may be split into a plurality of beams of light in the branch region 300A. The plurality of beams of light may pass through the plurality of waveguides 311. Although FIG. 8 illustrates that the light generated by the light source 310 is split into eight beams of light in the branch region 300A, this is an example, and the disclosure is not limited thereto.

The phase control region 300B may include a plurality of phase control elements 330 respectively arranged in the plurality of waveguides 311. For example, the plurality of phase control elements 330 may be arranged in a second direction DR2 perpendicular to the first direction DR1. A plurality of beams of light split in the branch region 300A may be respectively provided to the plurality of phase control elements 330. The plurality of phase control elements 330 may each have a variable refractive index that is electrically controlled. Phases of the plurality of beams of light passing through the plurality of phase control elements 330 may be determined according to refractive indices of the plurality of phase control elements 330. The plurality of phase control elements 330 may independently control the phases of the plurality of beams of light.

The amplification region 300C may include a plurality of optical amplifiers 340 respectively arranged in a plurality of waveguides 311. The plurality of optical amplifiers 340 may be arranged in the second direction DR2 perpendicular to the first direction DR1. The plurality of optical amplifiers 340 may each increase the intensity of an optical signal. For example, the optical amplifier described above may be applied to each of the plurality of optical amplifiers 340.

The emission region 300D may include a plurality of grid pattern groups 350. The plurality of grid pattern groups 350 may be arranged in the second direction DR2. The plurality of grid pattern groups 350 may be respectively connected to the plurality of optical amplifiers 340. The plurality of grid pattern groups 350 may respectively emit a plurality of beams of light amplified in the amplification region 300C. To this end, the plurality of grid pattern groups 350 may each include a plurality of grid patterns 350a that are periodically arranged. The plurality of grid patterns 350a may be arranged in the first direction DR1. A propagation direction of output light OL emitted by each of the plurality of grid pattern groups 350 may be determined by a phase difference between the plurality of beams of light split in the phase control region 300B, intervals between the plurality of grid patterns 350a, heights of the plurality of grid patterns 350a, and widths of the plurality of grid patterns 350a. For example, the propagation direction of the output light OL may have a component in the first direction DR1, a component in the second direction DR2, and a component in a third direction DR3 perpendicular to the first direction DR1 and the second direction DR2.

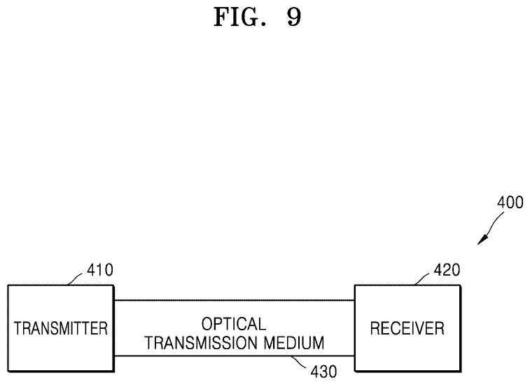

FIG. 9 is a block diagram illustrating an optical communication system 400 including an optical integration device, according one or more embodiments.

Referring to FIG. 9, the optical communication system 400 may include a transmitter 410, a receiver 420, and an optical transmission medium 430 that optically connects the transmitter 410 to the receiver 420. The transmitter 410 may convert an electrical signal into an optical signal and transmit the optical signal to the optical transmission medium 430. In an example, the electrical signal may include data to be transmitted to the receiver 420 through the optical transmission medium 430. In one or more embodiments, the electrical signal may also be generated by the transmitter 410 but may also be transmitted to the transmitter 410 from the outside of the transmitter 410. In one or more embodiments, the transmitter 410 may include a device capable of performing an electrical-optical conversion and may also include a driver for driving the device, but the disclosure is not limited thereto. In one or more embodiments, the transmitter 410 may include a light source that is connected to the optical transmission medium 430 by wire and generates an optical signal modulated in response to an electrical signal. In addition to the light source, the transmitter 410 may be implemented with an optical integrated device including a waveguide and an optical amplifier.

In one or more embodiments, the optical transmission medium 430 is optically connected to a transmitter and a receiver in optical communication, include an optical fiber for long-distance communication, and include the optical waveguide and optical amplifier described above for short-distance communication (for example, when the transmitter and the receiver are included in the same device or system), but the disclosure is not limited thereto.

In one or more embodiments, the receiver 420 may include a configuration for receiving an optical signal transmitted from the transmitter 410. Because an electrical signal generated by the transmitter 410 may be converted into an optical signal and then transmitted to the receiver 420 through the optical transmission medium 430, the receiver 420 may include an optical detector for detecting the optical signal transmitted from the optical transmission medium 430 and converting the optical signal into an electrical signal. In one or more embodiments, the optical detector may be a photoelectric conversion element. The receiver 420 may be implemented with an optical integrated device including a waveguide and an optical amplifier in addition to the optical detector. The receiver 420 may further include a processor for processing an electrical signal generated by the receiver 420.

Although the optical amplifier described above and the optical integrated device including the optical amplifier are described with reference to the embodiments illustrated in the drawings, this is merely an example, and those skilled in the art will understand that various modifications and equivalent other embodiments may be derived therefrom. Although many matters are specifically described above, the descriptions should be interpreted as examples of specific embodiments rather than limiting the scope of the disclosure. Therefore, the scope of rights should not be determined by the described embodiments, but by the technical ideas described in the patent claims.

Each of the embodiments provided in the above description is not excluded from being associated with one or more features of another example or another embodiment also provided herein or not provided herein but consistent with the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An optical integrated device comprising:
a first conductive layer;
a first semiconductor layer on the first conductive layer and doped with a first-type dopant;
a second semiconductor layer on the first semiconductor layer and spaced apart from the first semiconductor layer, the second semiconductor layer being doped with a second-type dopant having a polarity that is opposite to a polarity of the first-type dopant;
a second conductive layer on the second semiconductor layer; and
a third semiconductor layer between the first semiconductor layer and the second semiconductor layer, the third semiconductor layer comprising germanium and being configured to amplify light in response to an electrical signal being applied to the first conductive layer and the second conductive layer.

2. The optical integrated device of claim 1, wherein the third semiconductor layer comprises an intrinsic semiconductor.

3. The optical integrated device of claim 1, wherein the third semiconductor layer comprises at least one of Ge and GeₓSi₁₋ₓ, with (0<x<1).

4. The optical integrated device of claim 1, wherein each of the first semiconductor layer and the second semiconductor layer comprises silicon (Si).

5. The optical integrated device of claim 1, wherein the first semiconductor layer comprises silicon (Si), and
wherein the second semiconductor layer comprises germanium (Ge).

6. The optical integrated device of claim 5, wherein the first semiconductor layer comprises:
a first sub-semiconductor layer on the first conductive layer and comprising silicon (Si); and
a second sub-semiconductor layer on the first sub-semiconductor layer and comprising germanium (Ge).

7. The optical integrated device of claim 1, wherein a width of the third semiconductor layer is less than or equal to a width of the first semiconductor layer and a width of the second semiconductor layer.

8. The optical integrated device of claim 1, wherein the second semiconductor layer comprises:
a first region on the third semiconductor layer and having a width that is greater than a width of the third semiconductor layer; and
a second region on the first region and having a width that is less than the width of the first region.

9. The optical integrated device of claim 8, further comprising a dielectric layer on the first region and contacting a side surface of the second region.

10. The optical integrated device of claim 9, wherein the dielectric layer comprises at least one of a silicon oxide and a silicon nitride.

11. The optical integrated device of claim 1, further comprising a fourth semiconductor layer between the first semiconductor layer and the second semiconductor layer, the fourth semiconductor layer contacting a side surface of the third semiconductor layer.

12. The optical integrated device of claim 11, wherein the fourth semiconductor layer comprises silicon (Si).

13. The optical integrated device of claim 1, further comprising a fifth semiconductor layer comprising an amorphous material and between the first semiconductor layer and the third semiconductor layer.

14. The optical integrated device of claim 13, wherein the fifth semiconductor layer comprises at least one of Ge and GeₓSi₁₋ₓ, with (0<x<1).

15. The optical integrated device of claim 13, wherein a thickness of the fifth semiconductor layer is less than a thickness of the third semiconductor layer.

16. The optical integrated device of claim 1, further comprising a waveguide configured to transmit light passing therethrough to the third semiconductor layer.

17. The optical integrated device of claim 16, further comprising an anti-reflection layer between the waveguide and the third semiconductor layer and configured to prevent reflection of incident light.

18. An optical amplifier comprising:
a first semiconductor layer doped with a first-type dopant at a first concentration;
a second semiconductor layer on the first semiconductor layer and spaced apart from the first semiconductor layer, the second semiconductor layer doped with a second-type dopant having a polarity that is opposite to a polarity of the first-type dopant;
a conductive layer on the second semiconductor layer;
a third semiconductor layer on the first semiconductor layer and doped with the first-type dopant at a second concentration that is greater than the first concentration; and
a fourth semiconductor layer between the first semiconductor layer and the second semiconductor layer, the fourth semiconductor layer comprising germanium and being configured to amplify light in response to an electrical signal being applied to the conductive layer and the second semiconductor layer.

19. The optical amplifier of claim 18, wherein the third semiconductor layer comprises at least one of Ge and GeₓSi₁₋ₓ, with (0<x<1).

20. The optical amplifier of claim 18, wherein each of the first semiconductor layer and the second semiconductor layer comprises silicon (Si).
